(19) United States
(12) Patent Application Publication
(10) Pub. No.: US 2026/0372070 A1
(43) Pub. Date: Nov. 19, 2026

(54) Self-Heating Multi-Order Polynomial Temperature Trim

(71) Applicant: Allegro MicroSystems, LLC, Manchester, NH (US)

(72) Inventors: Tyler Daigle, Scarborough, ME (US); Steven Daubert, Bedford, NH (US); John Harrington, Pembroke, NH (US); Srujan Shivanakere, Nashua, NH (US)

(73) Assignee: Allegro MicroSystems, LLC, Manchester, NH (US)

(21) Appl. No.: 19/208,688

(22) Filed: May 15, 2025

(51) Int. Cl. H10W 40/10; H03K 17/14; H10W 40/00

(52) U.S. Cl. CPC H10W 40/10; H03K 17/14; H10W 40/00

(57) ABSTRACT

A self-heating semiconductor device is described. The semiconductor device includes a temperature sensitive circuit element configured to produce an uncorrected output signal. The semiconductor device also includes a first heating circuit and a second heating circuit disposed on-die. The heating circuits are configured to heat the temperature sensitive circuit element to different temperatures. The semiconductor device also includes a heating switch configured to selectively activate the first heating circuit to heat the temperature sensitive circuit element to a first temperature; or the second heating circuit to heat the temperature sensitive circuit element to a second temperature. The semiconductor device also includes a trimming circuit configured to correct the uncorrected output signal by providing a non-linear, polynomial temperature correction signal based at least in part on behavior of the temperature sensitive circuit element to the first temperature, the second temperature and a third, unheated temperature.

### BACKGROUND

A current sensor device can detect a current and output a voltage. The output voltage's relationship to the detected current has a given resolution (or sensitivity). In some cases, a current sensor may have temperature sensitive elements which influence the sensor's output response. Such influences can be corrected using a temperature trim signal.

Conventional techniques to determine a temperature trim code for a circuit look to determine what, if any, variations the circuitry exhibits over temperature. This information is then used to calculate the temperature trim code for the circuit. However, this process can be time consuming and expensive.

One method is to ramp the entire integrated (IC)'s temperature to each level to find the optimal trim code. Another method is to use a fixed temperature trim based on typical behavior and/or a room temp measured trim code. The ramping method can be more accurate but is expensive due to a significant test cost. The fixed temperature method does not require any significant test cost adder but is prone to errors resulting from part-to-part variation or mismatch.

### SUMMARY

In one aspect, a semiconductor device includes a temperature sensitive circuit element configured to produce an uncorrected output signal. The semiconductor device also includes a first heating circuit disposed on-die (e.g., inside/on the same semiconductor substrate) and a second heating circuit disposed on-die. The first heating circuit is configured to heat the temperature sensitive circuit element. The second heating circuit is also configured to heat the temperature sensitive circuit element. Additional heating circuits configured to heat the temperature sensitive circuit elements can optionally be included. The semiconductor device also includes a heating switch configured to selectively activate the first heating circuit to heat the temperature sensitive circuit element to a first temperature; or the second heating circuit to heat the temperature sensitive circuit element to a second temperature. The semiconductor device also includes a trimming circuit configured to correct the uncorrected output signal by providing a non-linear, polynomial temperature correction signal based at least in part on behavior of the temperature sensitive circuit element to the first temperature, the second temperature and a third, unheated temperature.

The semiconductor device may include a temperature sensing circuit configured to detect the temperature of the temperature sensitive circuit element.

The heating switch may be further configured to selectively activate the first heating circuit and the second heating circuit to heat the temperature sensitive circuit element to a fourth temperature. The non-linear, polynomial temperature correction signal is further based at least in part on behavior of the temperature sensitive circuit element to the fourth temperature.

The semiconductor device may include a magnetic field sensing element. The magnetic field sensing element may be any one of: a Hall effect transducer, a magnetoresistance sensor, a Tunnel Magnetoresistance (TMR) element and magnetic tunnel junction element (MTJ).

The non-linear, polynomial temperature correction signal may include a 2nd order temperature correction signal.

The semiconductor device may include a third heating circuit configured to heat the temperature sensitive circuit element. The heating switch may be configured to selectively activate the third heating circuit to heat the temperature sensitive circuit element to a fourth temperature. The non-linear, polynomial temperature correction signal is further based on the behavior of the temperature sensitive circuit element to the fourth temperature.

The first heating circuit and the second heating circuit may be disposed over the temperature sensitive circuit element.

The first heating circuit and the second heating circuit may be electronically parallel circuits.

The first heating circuit and the second heating circuit may be any one of: a serpentine metal trace and a heating coil.

The first heating circuit may have a resistance that is half a resistance of the second heating circuit.

The heating switch may be a MOS switch.

The semiconductor device may include a non-heated circuit element electrically connected to the temperature sensitive circuit element. The non-heated circuit element may be a temperature dependent component or the non-heated circuit element may be a non-temperature dependent component.

The temperature sensitive circuit element includes a reference resistor.

In another aspect, a method of trimming an integrated circuit (IC) is provided. The method includes activating a first heating circuit while a second heating circuit is deactivated in order to heat a temperature sensitive circuit element of the IC to a first temperature. A first untrimmed output signal value generated by the temperature sensitive circuit element at the first temperature in response to a first test signal is detected. A first trim code for the first temperature based on the first untrimmed output signal value is evaluated. The method also includes activating the second heating circuit while the first heating circuit is deactivated in order to heat the temperature sensitive circuit element to a second temperature. A second untrimmed output signal value generated by the temperature sensitive circuit element at the second temperature in response to a second test signal is detected. A second trim code for the second temperature based on the second untrimmed output signal value is evaluated. The method also includes deactivating the first heating circuit and the second heating circuit to allow the temperature sensitive circuit element to stabilize at a third temperature. A third untrimmed output signal value generated by the temperature sensitive circuit element at the third temperature in response to a third test signal is detected. A third trim code for the third temperature based on the third untrimmed output signal value is evaluated. The method also includes calculating temperature coefficients based on the first trim code, the second trim code and the third trim code and determining a non-linear, polynomial temperature correction curve for the temperature sensitive circuit using the temperature coefficients.

The method may also include activating both the first heating circuit and the second heating circuit to heat the temperature sensitive circuit element to a fourth temperature and detecting a fourth untrimmed output signal value generated by the temperature sensitive circuit element at the fourth temperature in response to a fourth test signal. Calculating the temperature coefficients may be further based on the fourth untrimmed output signal value.

The third temperature may be measured first, for example, before the first heating circuit and the second heating circuit are initially activated.

The method may also include configuring a trimming circuit to correct an output signal based on the non-linear, polynomial temperature correction curve to generate a temperature trimmed, coil compensated output signal.

### DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

FIG. 1 shows a conventional circuit capable of self-heating for temperature compensation.

FIG. 2 illustrates a circuit capable of self-heating to at least three-levels in accordance with an embodiment.

FIG. 3 illustrates another circuit capable of self-heating to at least three-levels in accordance with an embodiment.

FIG. 4 is a graph illustrating a sensor's sensitivity at three levels of sensitivity compensation in accordance with an embodiment.

FIG. 5 is a flow diagram of a trimming method for a circuit in accordance with an embodiment.

FIG. 6 is a block diagram of a self-heating IC in accordance with an embodiment.

### DETAIL DESCRIPTION

Described herein are various example embodiments that provide a sensor having multi-power level, on-die heating element placed over the temperature-dependent circuitry and temperature sensor. The heating element can be activated during an automated test program to determine the temperature trim. The sensor's characteristics can then be trimmed accordingly over temperature.

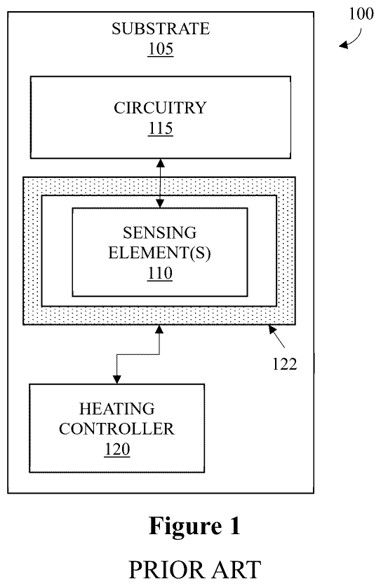

FIG. 1 shows a simple conventional circuit 100 capable of self-heating. The circuit 100 includes a substrate 105. Disposed on the substrate 105 is circuitry 115 and a sensing element 110. Also disposed on the substrate 105 is a heating element 122 which surrounds the sensing element 110. The heating element 122 may be controlled by a heating controller 120.

As noted above, a current sensor device, such as a magnetic sensor, may have a temperature sensitivity. The sensitivity can exhibit non-linear (non-first order) and unpredictable behavior over different temperatures. For example, a hall sensor may exhibit a large first- and second-order temperature coefficient that may vary slightly from part to part.

Typically, the temperature behavior can be corrected in the analog domain by adding a first order temperature correction and, possibly, a fixed-second order temperature correction to the signal path gain. Each part may get the same first order correction based on a typical characterized behavior, and any part-to-part variation results in a residual temperature error.

This residual error can be reduced by either using a room temperature trim value to calculate the magnitude of the first order correction or performing a multi-temperature trimming routine. Using the room temperature trim value assumes that the sensor's temperature behavior scales with room temperature behavior, but that is not always true. Some techniques use an external heating device to perform a multi-temperature trimming routine which includes ramping the entire IC temperature to a new level to get the temperature correction trim. This significantly increases the test cost due to multiple test insertions at different temperatures.

The temperature-dependent behavior can also be corrected in the digital domain by adjusting a sensitivity trim code based on a measured temperature. This method has significantly more freedom to add first, second, third, and higher order corrections. However, the underlying struggles of how to trim each individual part over temperature remain.

Various embodiments of the disclosure provide a semiconductor circuit, such as an IC, capable of self-heating the temperature dependent component for trimming. Self-heating is accomplished by forcing current through a long, narrow, serpentine metal trace or heating coil, for example. The narrow parts of the metal trace are routed over the temperature dependent component so that the heat is focused there.

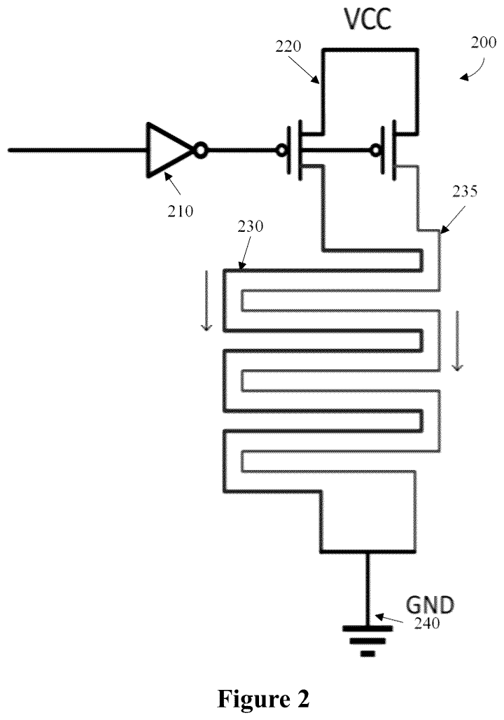

FIG. 2 illustrates a circuit 200 capable of self-heating to at least three-levels, in accordance with an embodiment. The circuit 200 includes an inverter 210 which controls a heating switch 220. The heating switch can direct power to either a first heating circuit 230 or a second heating circuit 235 (as well as to neither or both) which are connected to ground 240. In some embodiments, the first heating circuit 230 and the second heating circuit 235 may be metal traces. The first heating circuit 230 and the second heating circuit 235 may also have parallel heat coil segment.

Current can be activated with the heating switch 220 connecting the first heating circuit 230 and/or the second heating circuit 235 from supply to ground 240. The power dissipated, Pdis, in the metal trace is

$$Pdis = \frac{{Vdd}^{2}}{Rheat} ,$$

where Vdd is supply voltage, and Rheat is metal trace resistance.

The circuit 200 can achieve multiple levels of heating by selectively activating/deactivating the heating circuits 230, 235. For example, a first level may be associated with no heating, e.g., ambient temperature) when both the first heating circuit 230 and the second heating circuit 235 are deactivated. A second level may be associated with the first heating circuit 230 being activated and the second heating circuit 235 being deactivated. A third level may be achieved when the first heating circuit 230 is deactivated and the second heating circuit 235 is activated. A fourth level may be achieved by activating both the first heating circuit 230 and the second heating circuit 235.

In similar manner, adding additional heating circuits can achieve further heating levels. Additionally, by having different heating characteristics in the heating circuits (e.g., heating circuits 230, 235) the heating levels may be further controlled. For example, the heating circuit may be metal traces with one metal trace with twice the width of the other so that the resistance is approximately half. This results in about twice the power dissipating as heat.

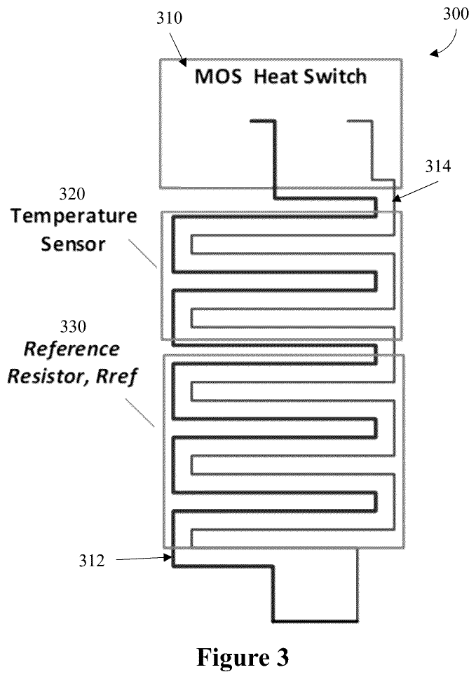

FIG. 3 illustrates another circuit 300 capable of self-heating to at least three-levels, in accordance with an embodiment. The circuit 300, which may be embodied in an integrated circuit, includes a MOS heating switch 310 which controls a first heating circuit 312 and a second heating circuit 314. Circuit 300 also includes a temperature sensor 320 and a heat sensitive element shown as a reference resistor 330. The circuit 300 is able to provide multiple levels of heating by selectively activating/deactivating the heating circuits 312, 314.

As shown, the first heating circuit 312 and second heating circuit 314 are disposed over the temperature sensor 320 and the reference resistor 330. This placement allows the heating circuits 312, 314 to efficiently heat only the temperature sensor 320 and the reference resistor 330. Other circuit elements, which do not change their response with temperature changes, are not heated by the heating circuits. Furthermore, this avoids using excess die area for the heating circuits (such as seen in FIG. 1).

By implementing multiple parallel metal traces, the power dissipated, or heat generated, can be programmable. Each heat switch can be activated during a trim procedure, for example, by applying a volatile register bit to adjust the self-heating power level. Once a heat switch setting is activated, the temperature will ramp to the new level over a short period of time. When using localized self-heating, the temperature slew is much faster than adjusting the entire IC temperature externally, such as done with some conventional techniques.

The temperature is measured from the temperature sensor to determine how much self-heating has occurred and when the temperature has stabilized. Once the temperature is stable, the sensor is trimmed over temperature, for example, the sensitivity trim code is adjusted until a target sensitivity is measured.

Depending on the desired accuracy and the level of temperature coefficients in the sensor's native temperature curve, a number of heat levels may be selected. For example, to trim out a sensor with first- and second-order coefficients, at least three temperature settings are trimmed. Three temperature settings can include room temperature and two levels of self-heating. The absolute accuracy of any of the temperatures is not of significant importance. Rather, the native performance at each temperature is the same whether temperature is forced externally (ambient) or internally (through self-heating). The response of sensitivity with respect to trim code may be trimmed so as to be as linear as possible.

Various embodiments may be used with a coil-compensated hall or other current sensor (for example, architectures in which a source of error over temperature is due to a single component or a sub-set of components). The residual error over temperature of an un-compensated hall signal path is typically the result of an on-chip resistor's error, reference voltage error, and transducer sensitivity error over temperature is given by Equation (1):

$$\frac{{V}_{0}}{{I}_{IN}} = {M}_{H} \cdot \frac{{V}_{ref}}{{R}_{ref}} \cdot {C}_{F} \cdot {S}_{H} , \qquad ( 1 )$$

where V₀ is the signal path front end output voltage (V), I_{IN} is input current (A), M_{H} is a scaling factor, V_{ref} is a bandgap voltage reference (V), R_{ref} is fixed resistance, S_{H} is the hall sensitivity

$$( \frac{V}{A \cdot G} ) ,$$

and C_{F} is an integrated conductor's coupling factor

$$( \frac{G}{A} ) .$$

Adding coil compensation gives Equation (2):

$$\frac{{V}_{0}}{{I}_{IN}} = {N}_{H} \cdot {R}_{ref} \cdot \frac{{C}_{F}}{{C}_{cf}} , \qquad ( 2 )$$

where N_{H} is a scaling factor, V_{ref} is bandgap voltage reference (V), C_{cf} is a fixed resistance, I_{coil} is coil current (A), R_{ref} is a fixed resistance used to generate

$${I}_{coil} = \frac{{V}_{ref}}{{R}_{ref}} .$$

Using these equations, the trim codes may be calculated. Once the trim codes at each temperature level are determined, the temperature coefficients can be calculated.

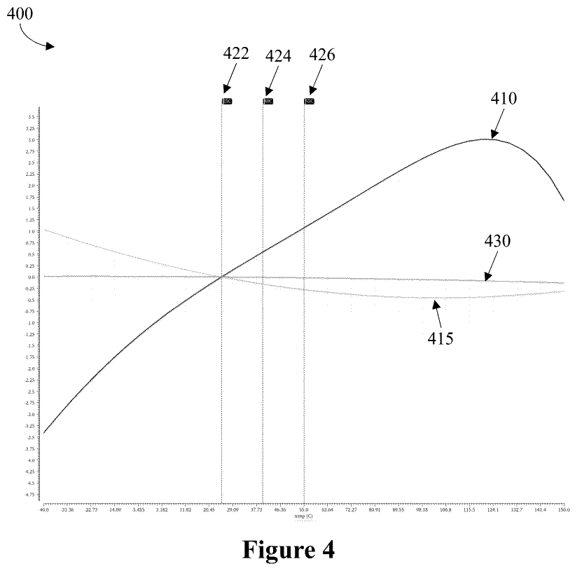

FIG. 4 is a graph 400 illustrating a given sensor's sensitivity at three (3) levels of sensitivity compensation. Three self-heating temperatures 422, 424 and 426 are used so that the trim can be calculated. It is understood that ambient temperature can also be used for compensation. The raw sensitivity is shown by line 410. This un-compensated sensitivity of this sensor has a temperature error dependent on a bandgap voltage reference, a reference resistor, and a hall plate. As shown, the sensitivity contains first-to fourth-order terms. For the illustrated embodiment, the coil compensated hall sensor's native sensitivity error, line 415, contains first and second coefficient terms. Multiple temperature dependent components and high order can make self-heating difficult.

Line 415 shows coil compensated sensitivity that also includes temperature error but it is dependent on the reference resistor. Single, contained temperature dependent components and low (e.g., second-) order make self-heating temperature trim more effective. Line 430 shows temperature trimmed, coil compensated sensitivity: As shown, the line 430 is near linear with an error of +/−0.2%.

The temperature trim can be done using a second-order digital polynomial temperature compensation in which the sensitivity trim code is adjusted over temperature based on the programmed (trimmed) temperature coefficients and the temperature sensor measurement. Thus, the temperature coefficients can be calculated using the measured optimal trim codes at each of the self-heating temperature levels 412, 414, 416 without changing the device temperature externally.

Accordingly, various embodiments provide techniques to trim a circuit using self-heating. Self-heating enables the trim to be performed without the use of an external heat source. Additionally, the self-heating elements may be used to heat selected components, such as a hall plate and a temperature sensor while avoiding heating other temperature dependent components. The self-heating elements may also be disposed directly on selected components in order to preserve space on the substrate. Measuring the response of the components at three or more heating levels allows the trimming process to determine non-linear, multi-order polynomial coefficients for a trimming curve in order to better correct the temperature responses of the selected components.

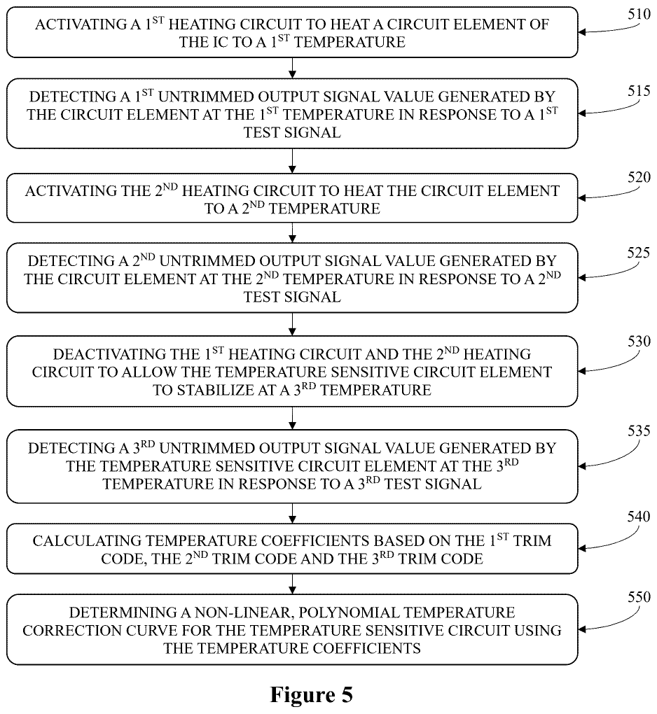

FIG. 5 is a flow diagram of a trimming method for a temperature sensitive integrated circuit (IC) in accordance with an embodiment. The method includes, at Block 510, activating a first heating circuit while a second heating circuit is deactivated in order to heat a temperature sensitive circuit element of the IC to a first temperature. A first untrimmed output signal value generated by the temperature sensitive circuit element at the first temperature in response to a first test signal is detected at Block 515. A first trim code for the first temperature based on the first untrimmed output signal value may be evaluated. The method also includes, at Block 520, activating the second heating circuit while the first heating circuit is deactivated in order to heat the temperature sensitive circuit element to a second temperature. A second untrimmed output signal value generated by the temperature sensitive circuit element at the second temperature in response to a second test signal is detected at Block 525. A second trim code for the second temperature based on the second untrimmed output signal value may be evaluated. The method also includes, at Block 530, deactivating the first heating circuit and the second heating circuit to allow the temperature sensitive circuit element to stabilize at a third temperature. A third untrimmed output signal value generated by the temperature sensitive circuit element at the third temperature in response to a third test signal is detected at Block 535. A third trim code for the third temperature based on the third untrimmed output signal value may be evaluated. The method also includes, at Block 540, calculating temperature coefficients based on the first trim code, the second trim code and the third trim code. At Block 545, the method includes determining a non-linear, polynomial temperature correction curve for the temperature sensitive circuit using the temperature coefficients.

The method may also include determining a non-linear, polynomial trim code based on the non-linear, polynomial temperature correction curve and storing the non-linear, polynomial trim code in a trimming circuit of the IC.

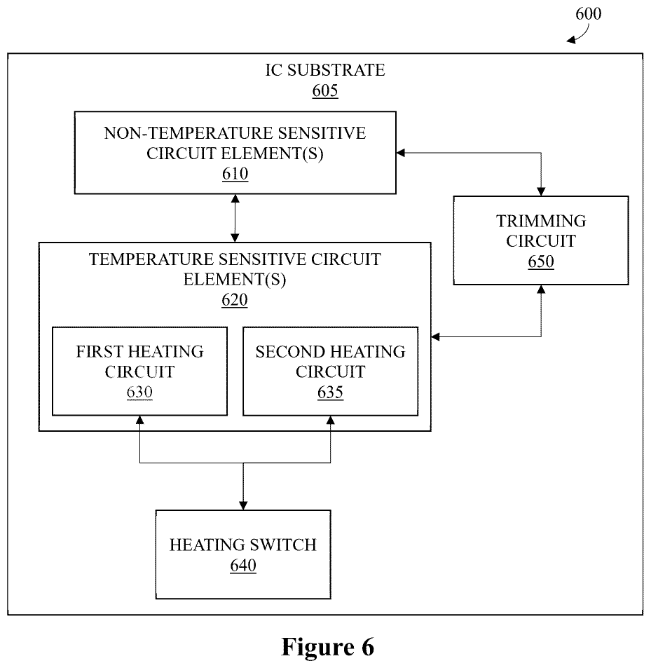

FIG. 6 is a block diagram of a self-heating IC 600 in accordance with an embodiment. The self-heating IC 600 includes an IC substrate 605. Disposed on the substrate 605 are a non-temperature sensitive circuit element 610 and a temperature sensitive circuit element 620. In thermal contact with the temperature sensitive circuit element 620 are a first heating circuit 630 and a second heating circuit 635. The first heating circuit 630 and the second heating circuit 635 may be located on-top of the temperature sensitive circuit element 620 or between the temperature sensitive circuit element 620 and the IC substrate 605. A heating switch 640 is also included in the self-heating IC 600. The heating switch 640 is configured to selectively activate the first heating circuit 630 and the second heating circuit 635, for example, to active the first heating circuit 630 while the second heating circuit 635 is deactivated, to active the second heating circuit 635 while the first heating circuit 630 is deactivated, to activate both the first heating circuit 630 and the second heating circuit 635 at the same time, or to deactivate both the first heating circuit 630 and the second heating circuit 635 at the same time.

The self-heating IC 600 may also include a trimming circuit 650. In some embodiment, the trimming circuit 650 may communicate with the temperature sensitive circuit element 620, for example, to determine a temperature of the temperature sensitive circuit element 620. The trimming circuit 650 may also communicate with the non-temperature sensitive circuit element 610, for example, to provide a trimming signal based on the temperature of the temperature sensitive circuit element 620. In other embodiments, the trimming circuit 650 may receive an uncorrected output signal from the temperature sensitive circuit element 620 and provide a trimmed signal to the non-temperature sensitive circuit element 610 based on the temperature sensitive circuit element 620.

Having described preferred embodiments, which serve to illustrate various concepts, structures, and techniques, which are the subject of this patent, it will now become apparent to those of ordinary skill in the art that other embodiments incorporating these concepts, structures and techniques may be used.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. An integrated circuit, comprising:
a temperature sensitive circuit element configured to produce an uncorrected output signal;
a first heating circuit disposed on-die, the first heating circuit configured to heat the temperature sensitive circuit element;
a second heating circuit disposed on-die, the second heating circuit configured to heat the temperature sensitive circuit element;
a heating switch configured to selectively activate:
the first heating circuit to heat the temperature sensitive circuit element to a first temperature; or
the second heating circuit to heat the temperature sensitive circuit element to a second temperature; and
a trimming circuit configured to correct the uncorrected output signal by providing a non-linear, polynomial temperature correction signal based at least in part on behavior of the temperature sensitive circuit element to the first temperature, the second temperature and a third, unheated temperature.

2. The integrated circuit of claim 1, further comprising a temperature sensing circuit configured to detect the temperature of the temperature sensitive circuit element.

3. The integrated circuit of claim 1, wherein the heating switch is further configured to selectively activate the first heating circuit and the second heating circuit to heat the temperature sensitive circuit element to a fourth temperature, and
wherein the non-linear, polynomial temperature correction signal is further based at least in part on behavior of the temperature sensitive circuit element to the fourth temperature.

4. The integrated circuit of claim 1, further comprising a magnetic field sensing element.

5. The integrated circuit of claim 4, wherein the magnetic field sensing element is one of: a Hall effect transducer, a magnetoresistance sensor, a Tunnel Magnetoresistance (TMR) element and magnetic tunnel junction element (MTJ).

6. The integrated circuit of claim 1, wherein the non-linear, polynomial temperature correction signal comprises a 2nd order temperature correction signal.

7. The integrated circuit of claim 1, further comprising a third heating circuit configured to heat the temperature sensitive circuit element,
wherein the heating switch configured to selectively activate the third heating circuit to heat the temperature sensitive circuit element to a fourth temperature, and
wherein the non-linear, polynomial temperature correction signal is further based on the behavior of the temperature sensitive circuit element to the fourth temperature.

8. The integrated circuit of claim 1, wherein the first heating circuit and the second heating circuit are disposed over the temperature sensitive circuit element.

9. The integrated circuit of claim 1, wherein the first heating circuit and the second heating circuit are electronically parallel circuits.

10. The integrated circuit of claim 1, wherein the first heating circuit is one of: a serpentine metal trace and a heating coil.

11. The integrated circuit of claim 1, wherein the first heating circuit has a resistance that is half a resistance of the second heating circuit.

12. The integrated circuit of claim 1, wherein the heating switch comprises a MOS switch.

13. The integrated circuit of claim 1, further comprising a non-heated circuit element electrically connected to the temperature sensitive circuit element.

14. The integrated circuit of claim 13, wherein the non-heated circuit element is a temperature dependent component.

15. The integrated circuit of claim 13, wherein the non-heated circuit element is a non-temperature dependent component.

16. The integrated circuit of claim 1, wherein the temperature sensitive circuit element comprises a reference resistor.

17. A method of trimming an integrated circuit (IC), comprising:
activating a first heating circuit while a second heating circuit is deactivated to heat a temperature sensitive circuit element of the IC to a first temperature;
detecting a first untrimmed output signal value generated by the temperature sensitive circuit element at the first temperature in response to a first test signal;
evaluating a first trim code for the first temperature based on the first untrimmed output signal value;
activating the second heating circuit while the first heating circuit is deactivated to heat the temperature sensitive circuit element to a second temperature;
detecting a second untrimmed output signal value generated by the temperature sensitive circuit element at the second temperature in response to a second test signal;
evaluating a second trim code for the second temperature based on the second untrimmed output signal value;
deactivating the first heating circuit and the second heating circuit to allow the temperature sensitive circuit element to stabilize at a third temperature;
detecting a third untrimmed output signal value generated by the temperature sensitive circuit element at the third temperature in response to a third test signal;
evaluating a third trim code for the third temperature based on the third untrimmed output signal value;
calculating temperature coefficients based on the first trim code, the second trim code and the third trim code; and
determining a non-linear, polynomial temperature correction curve for the temperature sensitive circuit using the temperature coefficients.

18. The method of claim 17, further comprising:
activating both the first heating circuit and the second heating circuit to heat the temperature sensitive circuit element to a fourth temperature; and
detecting a fourth untrimmed output signal value generated by the temperature sensitive circuit element at the fourth temperature in response to a fourth test signal,
wherein calculating the temperature coefficients is further based on the fourth untrimmed output signal value.

19. The method of claim 17, wherein the third temperature is measured first.

20. The method of claim 17, further comprising configuring a trimming circuit to correct an output signal based on the non-linear, polynomial temperature correction curve to generate a temperature trimmed, coil compensated output signal.
